(19) United States
(12) Patent Application Publication
(10) Pub. No.: US 2025/0386557 A1
(43) Pub. Date: Dec. 18, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiroyuki KISHIMOTO, Kanazawa Ishikawa (JP); Hiroki NEMOTO, Fuchu Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/953,489

(22) Filed: Nov. 20, 2024

(30) Foreign Application Priority Data
Jun. 18, 2024 (JP) 2024-098326

(51) Int. Cl. H01L 29/06; H01L 29/40; H01L 29/78

(52) U.S. Cl. CPC H10D 62/106; H10D 30/668; H10D 64/117

(57) ABSTRACT

A semiconductor device according to an embodiment includes: a semiconductor layer including a first conductivity type first semiconductor region; a first electrode; a second electrode; a second conductivity type second semiconductor region; a first conductivity type third semiconductor region electrically connected to the first electrode; a third electrode disposed in the semiconductor layer; a fourth electrode disposed in the semiconductor layer and electrically connected to the first electrode; a conductive portion in Schottky contact with the first semiconductor region; and a second conductivity type fourth semiconductor region disposed in the semiconductor layer. The conductive portion is disposed in the semiconductor layer so as to be electrically insulated from the second semiconductor region and electrically connected to the fourth electrode. The fourth semiconductor region extends downward from the second semiconductor region and faces the conductive portion with the first semiconductor region interposed therebetween.

### CROSS-REFERENCE TO RELATED APPLICATIONS

This application is based upon and claims the benefit of priority from Japanese Patent Application No. 2024-098326, filed on Jun. 18, 2024, the entire contents of which are incorporated herein by reference.

### FIELD

Embodiments described herein relate generally to a semiconductor device.

### BACKGROUND

As one of semiconductor devices, a MOSFET including a field plate electrode (also abbreviated as FPMOSFET or FPMOS) is known. By introducing a Schottky junction into the FPMOS, it is possible to reduce an operating voltage in a forward direction and to improve switching efficiency. On the other hand, the Schottky junction has a breakdown voltage lower than a PN junction, and therefore it is difficult to ensure a withstand voltage of the FPMOS.

### BRIEF DESCRIPTION OF THE DRAWINGS

FIG. 1 is a cross-sectional view of a semiconductor device according to a first embodiment;

FIG. 2 is an enlarged view of a region A in FIG. 1;

FIG. 3 is a diagram for explaining an operation when the semiconductor device according to the first embodiment is off;

FIG. 4 is a diagram for explaining an operation when the semiconductor device according to the first embodiment is off;

FIG. 5 is a diagram for explaining an operation of the semiconductor device according to the first embodiment when the semiconductor device is on;

FIG. 6A is a process cross-sectional view for explaining an example of a method for manufacturing the semiconductor device according to the first embodiment;

FIG. 6B is a process cross-sectional view for explaining the example of the method for manufacturing the semiconductor device according to the first embodiment, subsequent to FIG. 6A;

FIG. 6C is a process cross-sectional view for explaining the example of the method for manufacturing the semiconductor device according to the first embodiment, subsequent to FIG. 6B;

FIG. 6D is a process cross-sectional view for explaining the example of the method for manufacturing the semiconductor device according to the first embodiment, subsequent to FIG. 6C;

FIG. 6E is a process cross-sectional view for explaining the example of the method for manufacturing the semiconductor device according to the first embodiment, subsequent to FIG. 6D;

FIG. 6F is a process cross-sectional view for explaining the example of the method for manufacturing the semiconductor device according to the first embodiment, subsequent to FIG. 6E;

FIG. 6G is a process cross-sectional view for explaining the example of the method for manufacturing the semiconductor device according to the first embodiment, subsequent to FIG. 6F;

FIG. 6H is a process cross-sectional view for explaining the example of the method for manufacturing the semiconductor device according to the first embodiment, subsequent to FIG. 6G;

FIG. 6I is a process cross-sectional view for explaining the example of the method for manufacturing the semiconductor device according to the first embodiment, subsequent to FIG. 6H;

FIG. 6J is a process cross-sectional view for explaining the example of the method for manufacturing the semiconductor device according to the first embodiment, subsequent to FIG. 6I;

FIG. 6K is a process cross-sectional view for explaining the example of the method for manufacturing the semiconductor device according to the first embodiment, subsequent to FIG. 6I;

FIG. 6L is a process cross-sectional view for explaining the example of the method for manufacturing the semiconductor device according to the first embodiment, subsequent to FIG. 6K;

FIG. 6M is a process cross-sectional view for explaining the example of the method for manufacturing the semiconductor device according to the first embodiment, subsequent to FIG. 6L;

FIG. 6N is a process cross-sectional view for explaining the example of the method for manufacturing the semiconductor device according to the first embodiment, subsequent to FIG. 6M;

FIG. 6O is a process cross-sectional view for explaining the example of the method for manufacturing the semiconductor device according to the first embodiment, subsequent to FIG. 6N;

FIG. 7 is a cross-sectional view of a semiconductor device according to a second embodiment; and

FIG. 8 is an enlarged view of a region B in FIG. 7.

### DETAILED DESCRIPTION

A semiconductor device according to an embodiment includes: a semiconductor layer including a first conductivity type first semiconductor region; a first electrode disposed on an upper surface of the semiconductor layer; a second electrode disposed on a lower surface of the semiconductor layer and electrically connected to the first semiconductor region; a second conductivity type second semiconductor region disposed on the first semiconductor region in the semiconductor layer; a first conductivity type third semiconductor region disposed on the second semiconductor region in the semiconductor layer and electrically connected to the first electrode; a third electrode disposed in the semiconductor layer so as to face the second semiconductor region via a first insulating region along a second direction orthogonal to a first direction directed from the first electrode toward the second electrode; a fourth electrode disposed in the semiconductor layer so as to face the first semiconductor region via a second insulating region along the second direction and electrically connected to the first electrode; a conductive portion in Schottky contact with the first semiconductor region; and a second conductivity type fourth semiconductor region disposed in the semiconductor layer. The conductive portion is disposed in the semiconductor layer so as to be electrically insulated from the second semiconductor region and electrically connected to the fourth electrode. The fourth semiconductor region extends downward from the second semiconductor region and faces the conductive portion with the first semiconductor region interposed therebetween.

Hereinafter, embodiments according to the present invention will be described with reference to the drawings. The embodiments do not limit the present invention. The drawings are schematic or conceptual, and a ratio between portions and the like are not necessarily the same as actual ones. In the specification and the drawings, elements similar to those described above regarding the previously described drawings are denoted by the same reference numerals, and detailed description thereof is appropriately omitted.

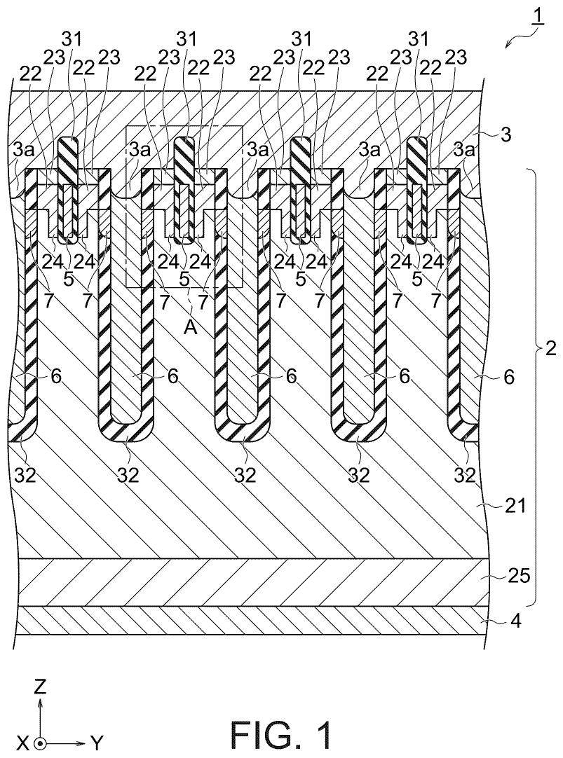

For convenience of description, an XYZ orthogonal coordinate system is adopted as illustrated in FIG. 1 and the like. The Z-axis direction is a stacking direction (thickness direction) in the semiconductor device. In the Z direction, a source electrode side is also referred to as “upper”, and a drain electrode side is also referred to as “lower”. Note that this expression is for convenience and independent of the direction of gravity. The Z-axis direction is the first direction in the claims. The Y-axis direction is the second direction in the claims.

In the following description, notations of n⁺, n, n⁻, p⁺, p, p⁻, and the like may be used to represent a relative level of impurity concentration in each conductivity type. That is, n⁺ indicates that an n-type impurity concentration is relatively higher than n, and n⁻ indicates that the n-type impurity concentration is relatively lower than n. In addition, p⁺ indicates that a p-type impurity concentration is relatively higher than p, and p⁻ indicates that the p-type impurity concentration is relatively lower than p. When both the p-type impurity and the n-type impurity are contained in each region, these notations represent a relative level of a net impurity concentration after these impurities have been compensated for.

The n-type, n⁺-type, and n⁻-type are examples of the first conductivity type in the claims. The p-type, p⁺-type, and p⁻-type are examples of the second conductivity type in the claims. Note that, in the following description, the n-type and the p-type may be inverted. That is, the first conductivity type may be p-type.

An impurity concentration of the semiconductor region can be measured by, for example, secondary ion mass spectrometry (SIMS). The relative level of the impurity concentration can also be determined from a level of a carrier concentration obtained by, for example, scanning capacitance microscopy (SCM).

In addition, dimensions such as a length and a width of the semiconductor region can be measured by, for example, analysis of a surface and/or a cross section by a transmission electron microscope (TEM), an energy dispersive X-ray spectroscopy (EDX), or a scanning electron microscope (SEM).

In addition, a composition of a conductive portion such as a source electrode, a drain electrode, a field plate electrode, or a Schottky metal can be analyzed by energy dispersive X-ray spectroscopy or the like.

### First Embodiment

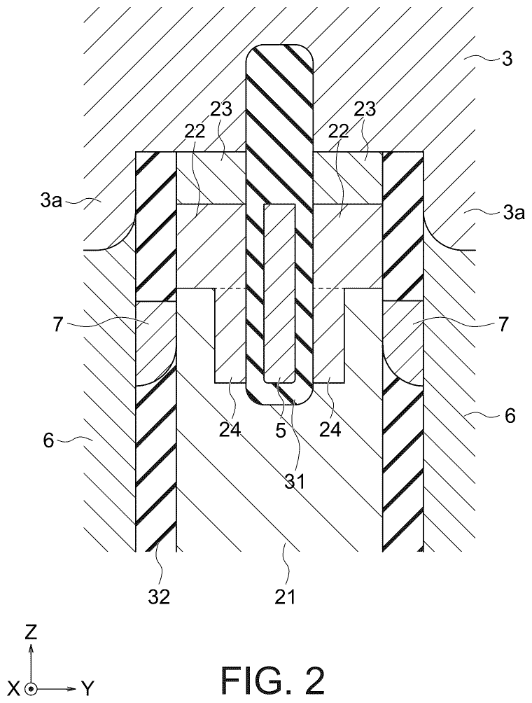

First, a configuration of a semiconductor device according to a first embodiment will be described with reference to FIGS. 1 and 2. FIG. 1 is a cross-sectional view of a semiconductor device 1 according to the first embodiment. FIG. 2 is an enlarged view of a region A in FIG. 1.

The semiconductor device 1 according to the present embodiment is a vertical transistor. More specifically, the semiconductor device 1 is a MOSFET including a field plate electrode and having a Schottky junction introduced therein.

As illustrated in FIG. 1, in the present embodiment, a gate electrode 5 and a field plate electrode 6 are aligned with each other in the Y-axis direction.

As illustrated in FIG. 1, the semiconductor device 1 includes a semiconductor layer 2, a source electrode 3 disposed on an upper surface of the semiconductor layer 2, a drain electrode 4 disposed on a lower surface of the semiconductor layer 2, the gate electrode 5, the field plate electrode 6, and a conductive portion 7.

Note that the source electrode 3 is an example of the first electrode in the claims, the drain electrode 4 is an example of the second electrode in the claims, and the gate electrode 5 is an example of the third electrode in the claims. The field plate electrode 6 is an example of the fourth electrode in the claims.

The source electrode 3, the drain electrode 4, and the gate electrode 5 function as a source electrode, a drain electrode, and a gate electrode of the MOSFET, respectively. In the present embodiment, the drain electrode 4 is electrically connected to a drain region 25 of the semiconductor layer 2.

The source electrode 3 has a contact plug 3a in contact with the field plate electrode 6. In the present embodiment, as illustrated in FIG. 1, the contact plug 3a is disposed in the semiconductor layer 2 via an insulating region 32. In the present embodiment, the source electrode 3 is electrically connected to the field plate electrode 6 via the contact plug 3a.

The source electrode 3 and the drain electrode 4 contain, for example, at least one of aluminum (Al), copper (Cu), titanium (Ti), and tungsten (W). For example, the source electrode 3 is made of aluminum or an AlCu alloy. The contact plug 3a may be made of the same material as the source electrode 3.

Note that, although not illustrated, the source electrode 3 may include a plurality of metal layers made of different materials. For example, the source electrode 3 may include a first metal layer made of titanium (Ti) and/or titanium nitride (TiN) disposed on the semiconductor layer 2, a second metal layer made of tungsten (W) disposed on the first metal layer, and a third metal layer made of aluminum (Al) disposed on the second metal layer.

In addition, a conductive film (not illustrated) of a barrier metal may be disposed between the semiconductor layer 2 (source region 23) and the source electrode 3. The conductive film contains, for example, titanium and/or tungsten.

The gate electrode 5 is disposed in the semiconductor layer 2 so as to face a base region 22 via the insulating region 31 along a direction (Y-axis direction) orthogonal to a thickness direction of the semiconductor layer 2 (direction directed from the drain electrode 4 toward the source electrode 3).

The gate electrode 5 is made of, for example, a conductive material such as polysilicon containing p-type or n-type impurities. The insulating region 31 covers an inner wall of a gate trench formed on an upper surface of the semiconductor layer 2 so as to reach a drift region 21. The insulating region 31 is made of a dielectric such as a silicon oxide or a silicon nitride. The insulating region 31 is an example of the first insulating region in the claims.

The gate electrode 5 is electrically insulated from the semiconductor layer 2 by the insulating region 31. When a voltage is applied to the gate electrode 5, an inversion layer (channel C described later) is formed in the base region 22 in the vicinity of an interface between the base region 22 and the insulating region 31.

The field plate electrode 6 is disposed in the semiconductor layer 2 so as to face the drift region 21 via the insulating region 32 along the Y-axis direction. The field plate electrode 6 is electrically connected to the source electrode 3. The insulating region 32 covers an inner wall of the gate trench formed on the upper surface of the semiconductor layer 2 so as to reach the drift region 21. The insulating region 32 is made of a dielectric such as a silicon oxide or a silicon nitride. The insulating region 32 is an example of the second insulating region in the claims.

In the present embodiment, the insulating region 31 and the insulating region 32 are disposed so as to sandwich the base region 22 along the Y-axis direction.

The field plate electrode 6 is made of, for example, a conductive material such as polysilicon containing p-type or n-type impurities or metal. The field plate electrode 6 is electrically insulated from the semiconductor layer 2 by the insulating region 32. With the field plate electrode 6, when the MOSFET is in an off state and a reverse voltage is applied between the source electrode 3 and the drain electrode 4, a depletion layer extends from the field plate electrode 6 to the drift region 21 around the field plate electrode 6. This depletion layer is in contact with and integrated with the depletion layer extending from an adjacent field plate electrode 6, whereby a withstand voltage of the MOSFET is improved.

The conductive portion 7 is made of a conductive material (Schottky metal), and is disposed in the semiconductor layer 2 so as to be electrically insulated from the base region 22 and electrically connected to the field plate electrode 6. The conductive portion 7 is in Schottky contact with the drift region 21. More specifically, as illustrated in FIGS. 1 and 2, the conductive portion 7 is disposed in the insulating region 32, is in ohmic contact with the field plate electrode 6 on a first side surface (a right side surface of the conductive portion 7 on the right side in FIG. 2), and is in Schottky contact with the drift region 21 on a second side surface (a left side surface of the conductive portion 7 on the right side in FIG. 2) opposite to the first side surface.

When the first conductivity type is n-type, the conductive portion 7 contains at least one of platinum (Pt), cobalt (Co), nickel (Ni), gold (Au), tungsten (W), and titanium (Ti). In the present embodiment, the conductive portion 7 is made of platinum. Note that the material of the conductive portion 7 is not limited to the above materials as long as the material is in Schottky contact with the drift region 21.

Various semiconductor regions (the drift region 21, the base region 22, the source region 23, an extension region 24, the drain region 25, and the like described later) are disposed in the semiconductor layer 2. In addition, the gate electrode 5 and the field plate electrode 6 are disposed in the semiconductor layer 2.

Note that the semiconductor layer 2 may be an epitaxial layer, a semiconductor substrate, or a semiconductor substrate and an epitaxial layer disposed on the semiconductor substrate. In the present embodiment, the semiconductor layer 2 is made of silicon (Si). In this case, for example, arsenic (As), phosphorus (P), or antimony (Sb) is used as the n-type impurity, and for example, boron (B) is used as the p-type impurity. A semiconductor material of the semiconductor layer 2 is not particularly limited, and may be, for example, a compound semiconductor such as silicon carbide (SiC) or gallium nitride (GaN) in addition to silicon.

Details of the semiconductor layer 2 will be described. As illustrated in FIG. 1, the drift region 21, the base region 22, the source region 23, the extension region 24, and the drain region 25 are disposed in the semiconductor layer 2. The drift region 21 and the drain region 25 are examples of the first semiconductor region in the claims, the base region 22 is an example of the second semiconductor region in the claims, the source region 23 is an example of the third semiconductor region in the claims, and the extension region 24 is an example of the fourth semiconductor region in the claims.

The drift region 21 functions as a drift region of the MOSFET. The drift region 21 is disposed on the drain region 25 (above the drain electrode 4) in the semiconductor layer 2. The drift region 21 is an n⁻-type semiconductor region. An n-type impurity concentration of the drift region 21 is, for example, 1×10¹⁵ cm⁻³ or more and 2×10¹⁶ cm⁻³ or less.

The drain region 25 functions as a drain region of the MOSFET. The drain region 25 is disposed between the drift region 21 and the drain electrode 4. The drain region 25 is, for example, an n⁺-type semiconductor region. An n-type impurity concentration of the drain region 25 is, for example, 1×10¹⁸ cm⁻³ or more and 1×10²¹ cm⁻³ or less.

Note that the drain region 25 does not have to be disposed. In this case, the drift region 21 is directly disposed on the drain electrode 4, and the drain electrode 4 is electrically connected to the drift region 21. Alternatively, the drift region 21 does not have to be disposed. In this case, for example, the drain region 25 is also disposed at the position of the drift region 21.

The base region 22 functions as a base region of the MOSFET. The base region 22 is disposed on the drift region 21 in the semiconductor layer 2. The base region 22 is a p-type semiconductor region. A p-type impurity concentration of the base region 22 is, for example, 1×10¹⁶ cm⁻³ or more and 1×10²⁰ cm⁻³ or less.

The source region 23 functions as a source region of the MOSFET. The source region 23 is disposed on the base region 22 in the semiconductor layer 2 and is electrically connected to the source electrode 3. The source region 23 is in ohmic contact with the source electrode 3. The source region 23 is an n⁺-type semiconductor region. An n-type impurity concentration of the source region 23 is, for example, 1×10¹⁸ cm⁻³ or more and 1×10²² cm⁻³ or less.

The extension region 24 is a second conductivity type semiconductor region disposed in the semiconductor layer 2 and extending downward (that is, toward the drain electrode 4) from the base region 22. In the present embodiment, the extension region 24 is a p-type semiconductor region. A p-type impurity concentration of the extension region 24 is substantially the same as the p-type impurity concentration of the base region 22, and is, for example, 1×10¹⁶ cm⁻³ or more and 1×10²⁰ cm⁻³ or less. Note that the p-type impurity concentration of the extension region 24 may be different from the p-type impurity concentration of the base region 22.

As illustrated in FIG. 2, the extension region 24 faces the conductive portion 7 with the drift region 21 interposed therebetween. In addition, in the present embodiment, the extension region 24 is disposed so as to face the gate electrode 5 via the insulating region 31.

### <Operation of Semiconductor Device 1>

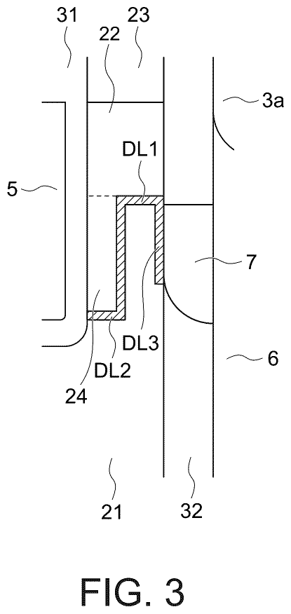

Next, an operation of the semiconductor device 1 will be described with reference to FIGS. 3 to 5.

FIG. 3 illustrates a partial cross section of the semiconductor device 1 when a potential of the gate electrode 5 is small, the MOSFET is in an off state, and a reverse voltage applied between the source electrode 3 and the drain electrode 4 is small. In this case, a depletion layer DL1 extends from a boundary between the base region 22 and the drift region 21 toward the drift region 21. A depletion layer DL2 extends from a boundary between the extension region 24 and the drift region 21 toward the drift region 21. A depletion layer DL3 extends from the conductive portion 7 toward the drift region 21.

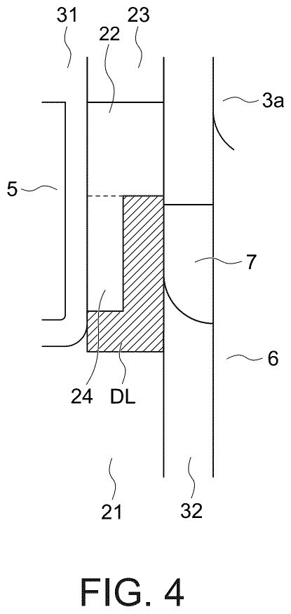

FIG. 4 illustrates a partial cross section of the semiconductor device 1 when a reverse voltage is increased from the state of FIG. 3. By the increase in reverse voltage, a width of the depletion layer extending from each of the base region 22, the extension region 24, and the conductive portion 7 increases. As a result, the depletion layer extending from each of the base region 22 and the extension region 24 comes into contact with the depletion layer extending from the conductive portion 7 to form one thick depletion layer DL as illustrated in FIG. 4. As a result, a withstand voltage of the Schottky junction portion is improved, and therefore a withstand voltage of the semiconductor device 1 which is an FPMOS can be improved.

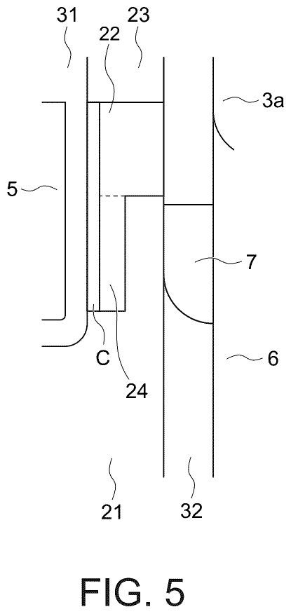

FIG. 5 illustrates a partial cross section of the semiconductor device 1 when a potential of the gate electrode 5 is large, the MOSFET is in an on state, and a reverse voltage is applied between the source electrode 3 and the drain electrode 4. In this case, a channel C is formed in the base region 22 in the vicinity of an interface between the base region 22 and the insulating region 31. In the present embodiment, since the extension region 24 is disposed so as to face the gate electrode 5 via the insulating region 31, the channel C is also formed in the extension region 24 in the vicinity of an interface between the extension region 24 and the insulating region 31. A current flows from the drain electrode 4 toward the source electrode 3 through the channel C. Note that, in this state, since a reverse voltage is not applied to a PN junction between the base region 22 and the drift region 21 or between the extension region 24 and the drift region 21, or a Schottky junction between the conductive portion 7 and the drift region 21, the depletion layer hardly extends.

Although not illustrated, when a forward voltage is applied between the source electrode 3 and the drain electrode 4, a current flows from the source electrode 3 toward the drain electrode 4. Specifically, a current flows from each of the base region 22 and the extension region 24 toward the drift region 21, and a current also flows from the conductive portion 7 toward the drift region 21.

### Operation and Effect

As described above, the semiconductor device 1 according to the first embodiment is an FPMOS including the field plate electrode 6, and includes the conductive portion 7 electrically insulated from the base region 22, electrically connected to the field plate electrode 6, and in Schottky contact with the drift region 21, and the extension region 24 disposed in the semiconductor layer 2, extending downward from the base region 22, and facing the conductive portion 7 with the drift region 21 interposed therebetween. As a result, when a large reverse voltage is applied between the source electrode 3 and the drain electrode 4 while the FPMOS is in an off state, the depletion layer extending from each of the base region 22 and the extension region 24 comes into contact and is integrated with the depletion layer extending from the conductive portion 7, and the drift region 21 sandwiched between the extension region 24 and the conductive portion 7 is depleted. As a result, a withstand voltage of the Schottky junction portion is improved, and a withstand voltage of the semiconductor device 1 can be improved.

In addition, according to the present embodiment, a forward voltage (Vf) during a forward operation can be reduced by introducing the Schottky junction. In addition, accumulation of minority carriers (holes in the present embodiment) is reduced by the Schottky contact, and therefore switching efficiency can be improved.

Note that, as illustrated in FIG. 2, an orthogonal projection of the extension region 24 onto an interface between the insulating region 31 and the drift region 21 may include a Schottky contact portion of the conductive portion 7 (a portion where the conductive portion 7 is in contact with the drift region 21). As a result, the drift region 21 sandwiched between the extension region 24 and the conductive portion 7 can be further depleted, and the withstand voltage can be further improved.

In addition, the width (length in the Y-axis direction) of the extension region 24 may be larger than the width of a portion of the drift region 21 sandwiched between the extension region 24 and the conductive portion 7. This makes it easy to deplete the portion over the entire width.

### <Method for Manufacturing Semiconductor Device 1>

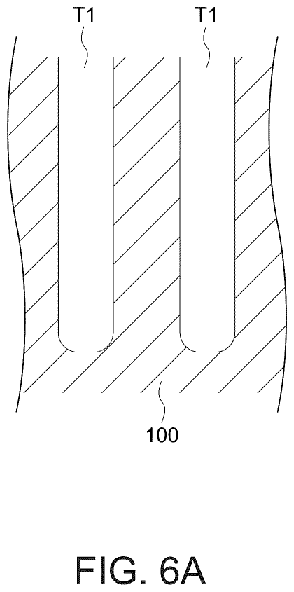

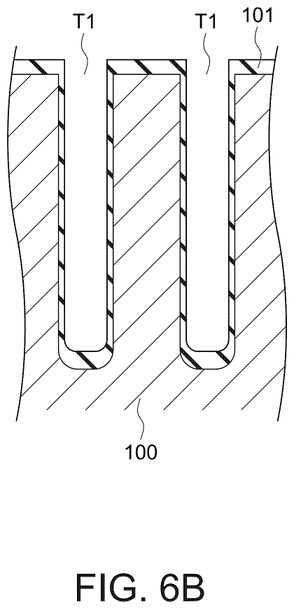

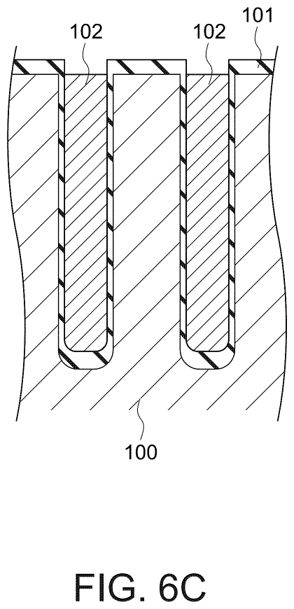

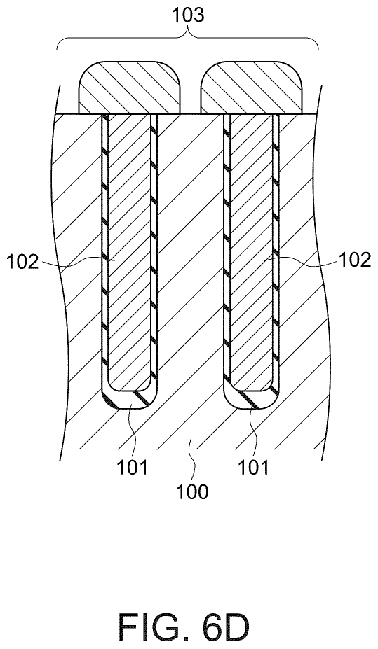

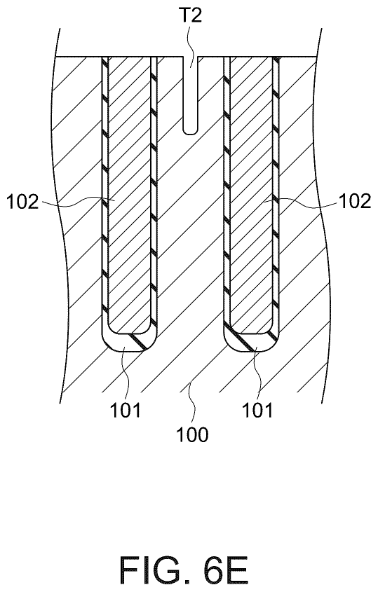

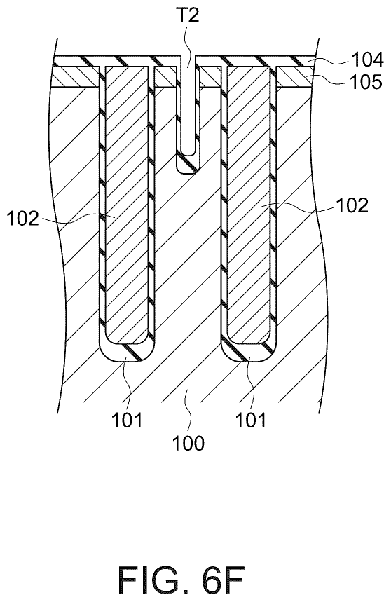

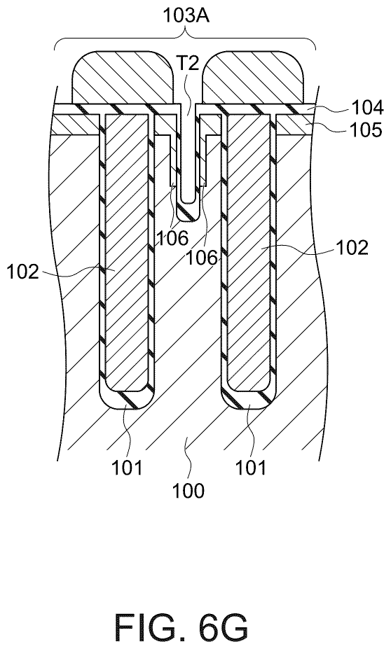

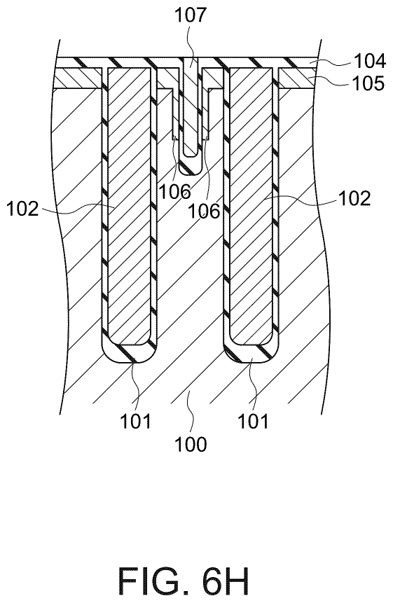

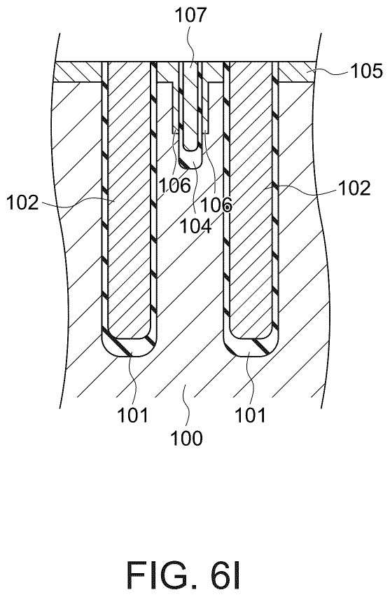

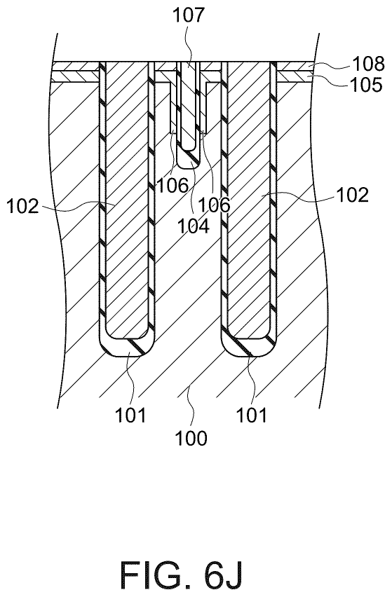

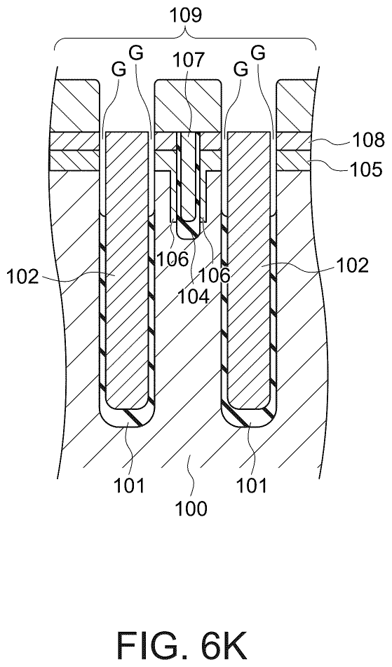

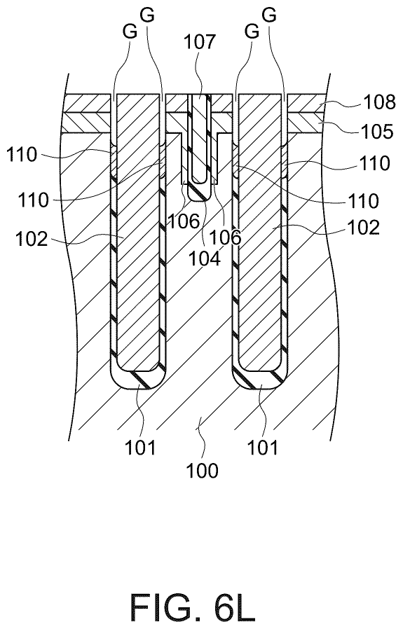

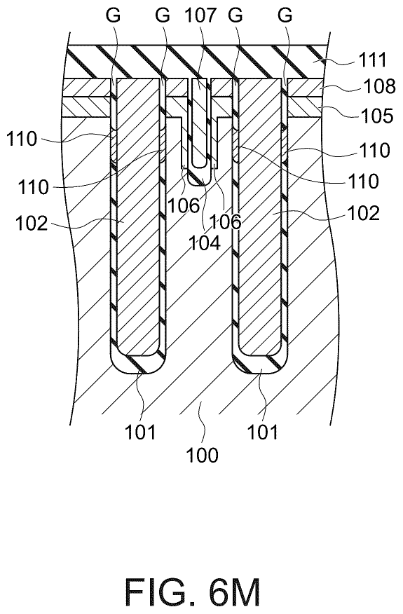

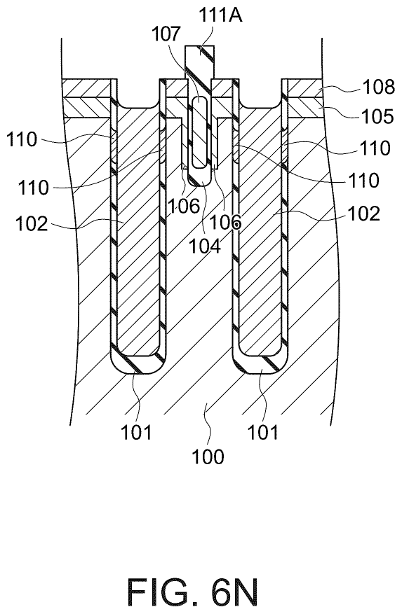

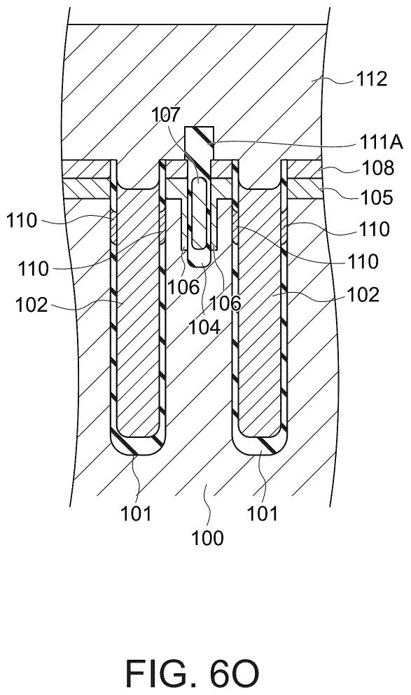

An example of a method for manufacturing the semiconductor device 1 will be described with reference to FIGS. 6A to 6O.

First, as illustrated in FIG. 6A, an n-type semiconductor layer 100 is prepared. There is an n-type semiconductor region in the semiconductor layer 100, and a part of the semiconductor region is the above-described drift region 21. The semiconductor layer 100 is made of, for example, silicon doped with n-type impurities. Note that the semiconductor layer 100 may be a semiconductor substrate (semiconductor wafer), may include a semiconductor substrate and an epitaxial layer deposited on the semiconductor substrate, or may include only an epitaxial layer.

Next, a trench T1 is formed on an upper surface of the semiconductor layer 100 by reactive ion etching (RIE) or the like. The trench T1 is a field plate trench for disposing a field plate electrode therein.

Next, as illustrated in FIG. 6B, an insulating region 101 is formed on an inner wall of the trench T1 and an upper surface of the semiconductor layer 100 by thermal oxidation or the like. The insulating region 101 is made of a silicon oxide, a silicon nitride, or the like. The insulating region 101 in the trench T1 is a field plate oxide film (FPOX) and corresponds to the above-described insulating region 32.

Next, as illustrated in FIG. 6C, a conductive material such as polysilicon is deposited in the insulating region 101 of the trench T1 and on the upper surface of the semiconductor layer 100 by chemical vapor deposition (CVD) such as reduced pressure CVD. Thereafter, surplus of the conductive material is etched back by chemical mechanical polishing (CMP), chemical dry etching (CDE), or the like to form a conductive portion 102. The conductive portion 102 corresponds to the above-described field plate electrode 6.

Next, as illustrated in FIG. 6D, the insulating region 101 on the upper surface of the semiconductor layer 100 is removed by etching using CDE or the like. Thereafter, a resist material is applied to the upper surface of the semiconductor layer 100, and a lithography step is performed to form a resist pattern 103. The resist pattern 103 covers the insulating region 101 and the conductive portion 102, and has an opening in a region where a gate electrode is to be formed.

Next, as illustrated in FIG. 6E, etching is performed by RIE or the like using the resist pattern 103 as an etching mask to form a trench T2 on the upper surface of the semiconductor layer 100. The trench T2 is a gate trench for disposing a gate electrode therein. After the trench T2 is formed, the resist pattern 103 is removed.

Next, as illustrated in FIG. 6F, an insulating region 104 is formed on an inner wall of the trench T2 and the upper surface of the semiconductor layer 100 by thermal oxidation or the like. The insulating region 104 is made of a silicon oxide, a silicon nitride, or the like. The insulating region 104 in the trench T2 is a gate oxide film and corresponds to the above-described insulating region 31. After the insulating region 104 is formed, p-type impurities are ion-implanted into the upper surface of the semiconductor layer 100 to form a semiconductor region 105. A part (lower portion) of the semiconductor region 105 is the base region 22. Note that the semiconductor region 105 may be formed before the insulating region 104 is formed.

Next, as illustrated in FIG. 6G, a resist material is applied to the upper surface of the semiconductor layer 100, and a lithography step is performed to form a resist pattern 103A. The resist pattern 103A covers the insulating region 104 located immediately above the insulating region 101 and the conductive portion 102, and has an opening. The opening includes a region where a gate electrode is to be formed, and is slightly wider than the trench T2.

After the resist pattern 103A is formed, p-type impurities are ion-implanted. Here, by performing ion implantation (inclined ion implantation) in which an ion implantation angle is set obliquely with respect to the upper surface of the semiconductor layer 100, a semiconductor region 106 extending downward from the semiconductor region 105 corresponding to the opening position of the resist pattern 103A is formed. The semiconductor region 106 is a semiconductor region corresponding to the extension region 24.

Next, as illustrated in FIG. 6H, the resist pattern 103A is removed, and then a conductive material such as polysilicon is deposited in the trench T2 and on the upper surface of the semiconductor layer 100 by CVD or the like. Thereafter, surplus of the conductive material is etched back by CMP, CDE, or the like to form a conductive portion 107. The conductive portion 107 corresponds to the gate electrode 5.

Next, as illustrated in FIG. 6I, the insulating region 104 and the conductive portion 107 on the upper surface of the semiconductor layer 100 are removed by etching such as CDE.

Next, as illustrated in FIG. 6J, n-type impurities are ion-implanted into the upper surface of the semiconductor layer 100 to form a semiconductor region 108 in an upper portion of the semiconductor region 105. The semiconductor region 108 corresponds to the source region 23.

Next, as illustrated in FIG. 6K, a resist material is applied to the upper surface of the semiconductor layer 100, and a lithography step is performed to form a resist pattern 109. The resist pattern 109 covers the insulating region 104 and the conductive portion 107, and has an opening in a region where the conductive portion 102 (field plate electrode) is formed. The insulating region 101 and the conductive portion 102 are exposed on a bottom surface of the opening, and the width of the opening is substantially equal to that of the trench T1.

After the resist pattern 109 is formed, a part of the insulating region 101 is removed by selective etching to form a groove G. For example, the insulating region 101 is etched away until a lower end of the groove G (an upper end of the insulating region 101) is located at substantially the same height as a lower end of the conductive portion 107. Note that the etching in this step may be dry etching or wet etching.

Next, as illustrated in FIG. 6L, the resist pattern 109 is removed, and then a conductive material (Schottky metal) is deposited in the groove G by CVD or the like. As the conductive material, a material having a relatively large work function and capable of forming a Schottky junction with an n-type semiconductor region of the semiconductor layer 100 is used. A conductive material containing at least one of, for example, platinum (Pt), cobalt (Co), nickel (Ni), gold (Au), tungsten (W), and titanium (Ti) is deposited in the groove G. Note that, in this step, the conductive material may be deposited up to an upper surface of the semiconductor region 108.

Thereafter, a part of the conductive material deposited in the groove G is removed by wet etching or the like. When the conductive material is deposited on the upper surface of the semiconductor region 108, the conductive material is also removed. In this step, in order to insulate the conductive material in the groove G from the semiconductor region (base region) 105, the conductive material is etched away until an upper end of the conductive material is located below a lower end of the semiconductor region 105. As a result, a conductive portion 110 is formed. The conductive portion 110 corresponds to the above-described conductive portion 7.

Next, as illustrated in FIG. 6M, an insulating film 111 is formed by CVD or the like so as to fill the groove G and to cover the upper surface of the semiconductor layer 100. A portion of the insulating film 111 filling the groove G constitutes a part (upper portion) of a field plate insulating film. The insulating film 111 is made of, for example, a silicon oxide or a silicon nitride.

After the insulating film 111 is formed, the insulating film 111 is thinly polished by CMP or the like. Thereafter, a resist material is applied onto the semiconductor layer 100, and a photolithography step is performed to form a resist pattern (not illustrated) having an opening above the conductive portion 102 and the conductive portion 107. Thereafter, etching is performed using the resist pattern as a mask to remove the conductive portion 102 and the conductive portion 107 to the height of an upper end of the semiconductor region 105. Next, an insulating film such as a silicon oxide film is formed on the semiconductor layer 100 so as to embed the conductive portion 102, the conductive portion 107, and the semiconductor region 108 by CVD or the like. Next, the insulating film is etched so as to leave a gate trench portion, and then the insulating film on the conductive portion 102 and the semiconductor region 108 is removed by etching. As a result, as illustrated in FIG. 6N, an insulating film 111A covering the gate trench portion is formed. As described above, by covering the conductive portion 107 serving as a gate electrode and disposing the insulating film 111A extending upward, insulation resistance can be improved.

Thereafter, a conductive material is deposited on the conductive portion 102, the semiconductor region 108, and the insulating film 111A by CVD, physical vapor deposition (PVD), or the like. As a result, a conductive portion 112 is formed as illustrated in FIG. 6O. The conductive material may be, for example, a metal material containing copper, titanium, tungsten, or aluminum, or may be polysilicon. The conductive portion 112 deposited on the conductive portion 102 corresponds to the above-described contact plug 3a, and the conductive portion 112 deposited on the semiconductor region 108 corresponds to the source electrode 3. Note that a barrier metal (not illustrated) may be formed before the conductive portion 112 is formed.

Thereafter, ion implantation is performed on a lower surface of the semiconductor layer 100 to form a drain region, and a conductive material is deposited on the lower surface of the semiconductor layer 100 by CVD, PVD, or the like to form a drain electrode (not illustrated). Note that the drain region and/or the drain electrode may be formed in advance before the trench T1 is formed.

Through the above steps, the semiconductor device 1 according to the first embodiment is manufactured. Note that the above manufacturing method is an example, and various modifications are conceivable.

### Second Embodiment

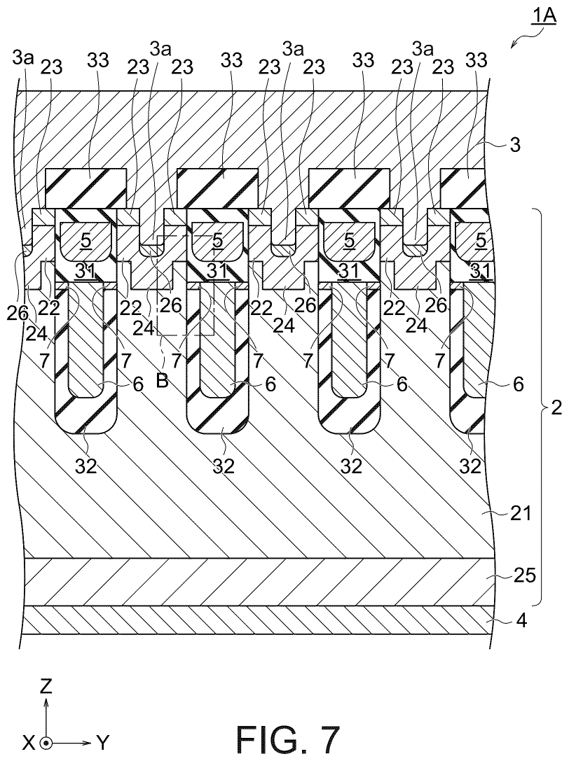

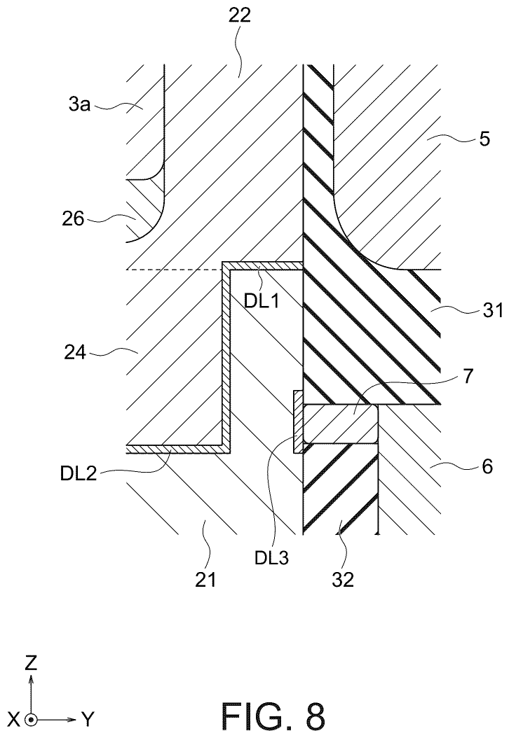

A semiconductor device according to a second embodiment will be described with reference to FIGS. 7 and 8. FIG. 7 is a partial cross-sectional view of a semiconductor device 1A according to the second embodiment. In FIG. 7, components having functions equivalent to those in FIG. 1 are denoted by the same reference numerals. FIG. 8 is an enlarged view of a region B in FIG. 7. FIG. 8 illustrates a state in which a reverse voltage is applied between a source electrode 3 and a drain electrode 4 while the MOSFET is in an off state.

One of differences between the second embodiment and the first embodiment is disposition of a field plate electrodes. In the present embodiment, a gate electrode and a field plate electrode are disposed in the same trench so as to be aligned with each other in a thickness direction (Z-axis direction) of a semiconductor layer. Hereinafter, the second embodiment will be described focusing on the differences.

As illustrated in FIG. 7, the semiconductor device 1A includes a semiconductor layer 2, the source electrode 3 disposed on an upper surface of the semiconductor layer 2, the drain electrode 4 disposed on a lower surface of the semiconductor layer 2, a gate electrode 5, a field plate electrode 6, and a conductive portion 7.

In the present embodiment, the insulating region 31 (first insulating region) in which the gate electrode 5 is disposed and the insulating region 32 (second insulating region) in which the field plate electrode 6 is disposed are disposed such that the insulating region 31 is located above the insulating region 32 along the Z-axis direction.

The conductive portion 7 of the present embodiment is disposed between the insulating region 31 and the insulating region 32. As in the first embodiment, the conductive portion 7 is in ohmic contact with the field plate electrode 6 on a first side surface (a right side surface in FIG. 8), and is in Schottky contact with the drift region 21 on a second side surface (a left side surface in FIG. 8) opposite to the first side surface. Note that, in FIGS. 7 and 8, the conductive portion 7 is disposed on each of a left side and a right side of the field plate electrode 6, but the conductive portion 7 may be disposed integrally so as to cover an upper surface of the field plate electrode 6 (in other words, so as to straddle the field plate electrode 6).

In addition, in the present embodiment, in order to reduce recovery loss, a high concentration region 26 is disposed in a portion adjacent to a bottom portion of the contact plug 3a. The high concentration region 26 is a p⁺-type semiconductor region having a p-type impurity concentration higher than that of the base region 22. The p-type impurity concentration of the high concentration region 26 is, for example, 1×10¹⁸ cm⁻³ or more and 1×10²¹ cm⁻³ or less. With the high concentration region 26, minority carriers accumulated in the base region 22 are injected into the high concentration region 26, pass through the contact plug 3a, and are discharged to the source electrode 3.

A barrier metal conductive film (not illustrated) may be disposed between the source electrode 3 and each of an interlayer insulating film 33, the source region 23, the base region 22, and the high concentration region 26. The conductive film contains, for example, titanium and/or tungsten.

The extension region 24 is a semiconductor region disposed below the contact plug 3a and extending downward (that is, toward the drain electrode 4) from the base region 22. The extension region 24 faces the conductive portion 7 with the drift region 21 interposed therebetween. The extension region 24 of the present embodiment is formed by inclined ion implantation or the like as in the first embodiment.

Note that the width of the extension region 24 may be equal to or more than a half of the width of a portion of the drift region 21 sandwiched between adjacent insulating regions 32 (substantially equal to the width of the base region 22). This makes it easy to deplete the portion over the entire width.

As illustrated in FIG. 8, when a small reverse voltage is applied between the source electrode 3 and the drain electrode 4 while the MOSFET in an off state, a depletion layer DL1 extends from a lower end of the base region 22, a depletion layer DL2 extends from a lower end and a side end of the extension region 24, and a depletion layer DL3 extends from the conductive portion 7. When the reverse voltage is increased, as in the first embodiment, the width of the depletion layer extending from each of the base region 22, the extension region 24, and the conductive portion 7 increases. As a result, the depletion layer extending from each of the base region 22 and the extension region 24 comes into contact with the depletion layer extending from the conductive portion 7 to form one thick depletion layer.

According to the second embodiment, as in the first embodiment, the extension region 24 extending downward from the base region 22 and facing the conductive portion 7 with the drift region 21 interposed therebetween is included. As a result, a withstand voltage of the Schottky junction portion is improved, and therefore a withstand voltage of the semiconductor device 1A which is an FPMOS can be improved.

Note that, as illustrated in FIG. 8, an orthogonal projection of the extension region 24 onto an interface between the insulating regions 31 and 32 and the drift region 21 may include a Schottky contact portion of the conductive portion 7 (a portion where the conductive portion 7 is in contact with the drift region 21). As a result, the drift region 21 sandwiched between the extension region 24 and the conductive portion 7 can be further depleted, and the withstand voltage can be further improved.

In addition, in FIG. 8, an upper end of the conductive portion 7 is substantially equal to an upper end of the field plate electrode 6, but the conductive portion 7 may extend toward the gate electrode 5 within a range not coming into contact with the gate electrode 5 or the base region 22 without being limited thereto.

The embodiments according to the present invention have been described above. In the embodiments described above, the trench in which the gate electrode 5 and the field plate electrode 6 are disposed is in a stripe shape in which the trenches are disposed in parallel. The shape of the trench is not limited thereto, and may be a mesh shape in which the trenches intersect with each other when viewed in the Z-axis direction, or may be a dot shape.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor layer including a first conductivity type first semiconductor region;
a first electrode disposed on an upper surface of the semiconductor layer;
a second electrode disposed on a lower surface of the semiconductor layer and electrically connected to the first semiconductor region;
a second conductivity type second semiconductor region disposed on the first semiconductor region in the semiconductor layer;
a first conductivity type third semiconductor region disposed on the second semiconductor region in the semiconductor layer and electrically connected to the first electrode;
a third electrode disposed in the semiconductor layer so as to face the second semiconductor region via a first insulating region along a second direction orthogonal to a first direction directed from the first electrode toward the second electrode;
a fourth electrode disposed in the semiconductor layer so as to face the first semiconductor region via a second insulating region along the second direction and electrically connected to the first electrode;
a conductive portion disposed in the semiconductor layer so as to be electrically insulated from the second semiconductor region and electrically connected to the fourth electrode and in Schottky contact with the first semiconductor region; and
a second conductivity type fourth semiconductor region disposed in the semiconductor layer so as to extend downward from the second semiconductor region and to face the conductive portion with the first semiconductor region interposed therebetween.

2. The semiconductor device according to claim 1, wherein the first insulating region and the second insulating region are disposed so as to sandwich the second semiconductor region along the second direction, and the conductive portion is disposed in the second insulating region.

3. The semiconductor device according to claim 2, wherein the conductive portion is in ohmic contact with the fourth electrode on a first side surface, and is in Schottky contact with the first semiconductor region on a second side surface opposite to the first side surface.

4. The semiconductor device according to claim 2, wherein the fourth semiconductor region is disposed so as to face the third electrode via the first insulating region.

5. The semiconductor device according to claim 2, wherein a width of the fourth semiconductor region is larger than a width of a portion of the first semiconductor region sandwiched between the fourth semiconductor region and the conductive portion.

6. The semiconductor device according to claim 2, wherein an orthogonal projection of the fourth semiconductor region onto an interface between the second insulating region and the first semiconductor region includes a Schottky contact portion of the conductive portion.

7. The semiconductor device according to claim 2, wherein the conductive portion contains at least one of platinum (Pt), cobalt (Co), nickel (Ni), gold (Au), tungsten (W), and titanium (Ti).

8. The semiconductor device according to claim 1, wherein the first insulating region and the second insulating region are disposed such that the first insulating region is located above the second insulating region along the first direction, and the conductive portion is disposed between the first insulating region and the second insulating region.

9. The semiconductor device according to claim 8, wherein the conductive portion is in ohmic contact with the fourth electrode on a first side surface, and is in Schottky contact with the first semiconductor region on a second side surface opposite to the first side surface.

10. The semiconductor device according to claim 8, wherein the fourth semiconductor region is disposed below a contact plug of the first electrode.

11. The semiconductor device according to claim 8, wherein an orthogonal projection of the fourth semiconductor region onto an interface between the second insulating region and the first semiconductor region includes a Schottky contact portion of the conductive portion.

12. The semiconductor device according to claim 8, wherein the conductive portion contains at least one of platinum (Pt), cobalt (Co), nickel (Ni), gold (Au), tungsten (W), and titanium (Ti).

13. The semiconductor device according to claim 1, wherein an orthogonal projection of the fourth semiconductor region onto an interface between the second insulating region and the first semiconductor region includes a Schottky contact portion of the conductive portion.

14. The semiconductor device according to claim 1, wherein the conductive portion contains at least one of platinum (Pt), cobalt (Co), nickel (Ni), gold (Au), tungsten (W), and titanium (Ti).

15. The semiconductor device according to claim 1, wherein the semiconductor layer includes silicon, silicon carbide, or gallium nitride.

16. The semiconductor device according to claim 1, wherein the first electrode is a source electrode, the second electrode is a drain electrode, the third electrode is a gate electrode, and the fourth electrode is a field plate electrode.

17. The semiconductor device according to claim 1, wherein the first conductivity type is n-type, and the second conductivity type is p-type.
